(19) United States
(12) Patent Application Publication
(10) Pub. No.: US 2008/0024397 A1
(43) Pub. Date: Jan. 31, 2008

(54) Output driver and diplay device

(76) Inventors: Tetsuro Oomori, Osaka (JP); Mamoru Seike, Osaka (JP); Junichi Suenaga, Kyoto (JP)

Correspondence Address: MCDERMOTT WILL & EMERY LLP, 600 13TH STREET, NW, WASHINGTON, DC, 20005-3096, US

(21) Appl. No.: 11/878,032

(22) Filed: Jul. 20, 2007

(30) Foreign Application Priority Data
Jul. 26, 2006 (JP) 2006-203342

(51) Int. Cl. G09G 3/28; H03B 1/00

(52) U.S. Cl. 345/60; 327/111

(57) ABSTRACT

First and second current sources are turned ON/OFF according to display data. A first input transistor has a source connected to a first potential, a drain connected to a second potential via the first current source, and a gate, the drain and the gate being coupled together. A second input transistor has a source connected to the first potential, a drain connected to the second potential via the second current source, and a gate which receives a gate voltage of the first input transistor. A first output transistor has a source connected to the first potential, a drain, and a gate receiving the drain voltage of the second input transistor. A second output transistor has a source connected to the second potential, a drain connected to the drain of the first output transistor, and a gate which receives a control signal corresponding to the display data.

### BACKGROUND OF THE INVENTION

1. Field of the Invention

The present invention relates to a capacitive load driver and specifically to a driver used as a display driver for PDP (Plasma Display Panel), etc., and a display device.

2. Description of the Prior Art

FIG. 10 shows a general structure of a conventional output driver. The conventional output driver includes a level shifter 91, an inverter 92, and an output circuit 93. The level shifter 91 is formed by four transistors including transistors 903 and 904 with high breakdown voltage drains and gates (15 V or higher) and transistors 901 and 902 with high breakdown voltage drains and low breakdown voltage gates (10 V or lower). The inverter 92 is formed by transistors 92p and 92n. The output circuit 93 is formed by transistors 93p and 93n.

The transistor 901 has a source connected to the second potential (e.g., ground potential) and a gate which receives input signal S901. The transistor 902 has a source connected to the second potential and a gate which receives input signal S902. The transistor 903 has a source connected to the first potential (e.g., supply potential) and a drain connected to the drain of the transistor 901 and the gate of the transistor 904. The transistor 903 has a gate connected to the drain of the transistor 904 and the drain of the transistor 902. The transistor 904 has a source connected to the first potential, a drain connected to the drain of the transistor 902 and the gate of the transistor 903, and a gate connected to the drain of the transistor 903 and the drain of the transistor 901. The drain voltage of the transistor 904 equals the output of the level shifter 91.

The transistor 92p has a source connected to the first potential, a drain connected to the drain of the transistor 92n, and a gate which receives the output of the level shifter 91. The transistor 92n has a source connected to the second potential, a drain connected to the drain of the transistor 92p, and a gate which receives control signal S92n. Drain voltage Vo of the transistor 92p equals the output of the inverter 92.

The transistor 93p has a source connected to the first potential, a drain connected to the drain of the transistor 93n, and a gate which receives output Vo of the inverter 92. The transistor 93n has a source connected to the second potential, a drain connected to the drain of the transistor 93p, and a gate which receives control signal S93n.

Next, the operation of the output driver shown in FIG. 10 is described. In the conventional output driver, when input signal S901 transitions to “L level” while input signal S902 transitions to “H level”, the transistor 901 is turned “OFF” while the transistor 902 is turned “ON”. Therefore, the gate of the transistor 904 rises (i.e., the gate voltage transitions from “L level” to “H level”) while the gate of the transistor 903 falls (i.e., the gate voltage transitions from “H level” to “L level”).

Then, when input signal S901 transitions to “H level” while input signal S902 transitions to “L level”, the transistor 901 is turned “ON” while the transistor 902 is turned “OFF”. Therefore, the gate of the transistor 903 rises while the gate of the transistor 904 falls. Accordingly, output Vo of the level shifter 91 rises, so that the gate of the transistor 92p rises. On the other hand, control signal S92n transitions to “H level”, so that the gate of the transistor 92n rises. As a result, the gate of the transistor 93p falls, so that the output current of the transistor 93p increases, and the charge current to the load also increases. In this way, the load is driven.

In the conventional output driver, however, the gates of the transistors of the output circuit are driven at a high speed by the inverter. Therefore, the output voltage changes depending on the load capacitance (e.g., the load capacitance of the display panel). The output voltage of each of a plurality of output drivers mounted on the display panel rises or falls according to display data input to the output driver. Herein, the output voltage of each of the output drivers has a rising/falling time which varies according to the coupling effect of inter-terminal capacitance or the conditions of neighboring output terminals.

### SUMMARY OF THE INVENTION

An objective of the present invention is to prevent the change of the output voltage from depending on the load capacitance.

According to an aspect of the present invention, an output driver includes: first and second current sources which are turned ON/OFF according to display data; a first input transistor which has a source connected to a first potential, a drain connected to a second potential via the first current source, and a gate, the drain and the gate being coupled together; a second input transistor which has a source connected to the first potential, a drain connected to the second potential via the second current source, and a gate receiving a gate voltage of the first input transistor; a first output transistor which has a source connected to the first potential, a drain, and a gate receiving the drain voltage of the second input transistor; and a second output transistor which has a source connected to the second potential, a drain connected to the drain of the first output transistor, and a gate receiving a control signal corresponding to the display data.

In this output driver, the drain voltage of the first output transistor is output as the output voltage. For example, when the first current source is OFF while the second current source is ON, a constant current flows between the gate of the first output transistor and the second current source. Herein, the slew rate of the gate voltage of the first output transistor is “I/C”, and the slew rate of the drain voltage of the first output transistor is “i/CL”, where “I” represents the constant current, “C” represents the gate-drain capacitance of the first output transistor, “i” represents the current drivability of the first output transistor, and “CL” represents the output load capacitance. If slew rate “i/CL” is larger than slew rate “I/C”, the change of the output voltage depends on slew rate “I/C”. Since slew rate “I/C” is constant, the output voltage does not depend on the load capacitance but changes at a constant rate. Thus, driving of high quality can be realized.

### BRIEF DESCRIPTION OF THE DRAWINGS

FIG. 1 shows a structure of an output driver according to embodiment 1 of the present invention.

FIG. 2 shows a structure of an output driver according to embodiment 2 of the present invention.

FIG. 3 shows a structure of an output driver according to embodiment 3 of the present invention.

FIG. 4 shows a structure of an output driver according to embodiment 4 of the present invention.

FIG. 5 shows a structure of an output driver according to embodiment 5 of the present invention.

FIG. 6 shows a structure of an output driver according to embodiment 6 of the present invention.

FIG. 7 shows a structure of an output driver according to embodiment 7 of the present invention.

FIG. 8 shows a structure of an output driver according to embodiment 8 of the present invention.

FIG. 9 shows a structure of a display device according to embodiment 9 of the present invention.

FIG. 10 shows a structure of a conventional output driver.

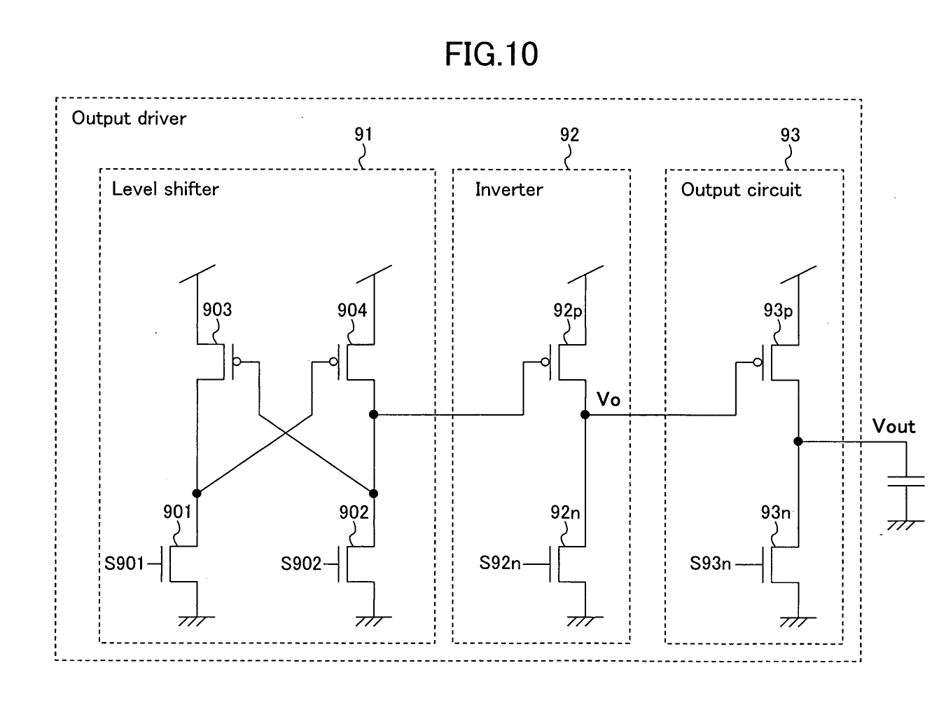

### DESCRIPTION OF THE PREFERRED EMBODIMENTS

Hereinafter, embodiments of the present invention will be described in detail with reference to the drawings. It should be noted that like or equivalent elements are denoted by like reference numerals, and the descriptions thereof are not repeated.

### Embodiment 1

<General Structure>

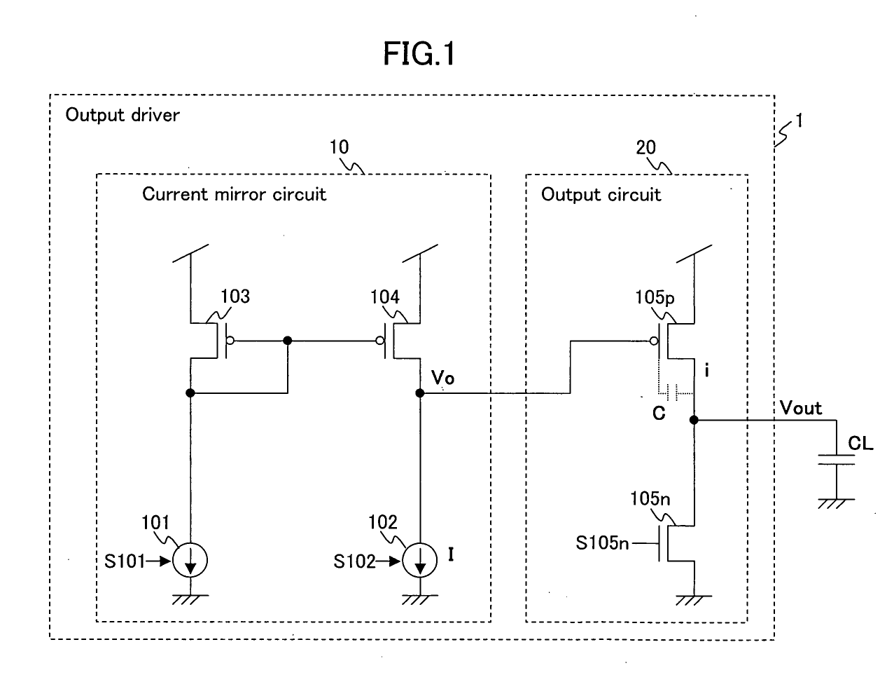

FIG. 1 shows a structure of an output driver according to embodiment 1 of the present invention. The output driver 1 is a device for supplying data signals to a plurality of display lines (not shown) of a display device, such as a plasma display, or the like. Specifically, the output driver 1 converts the voltage level of received display data to a high breakdown voltage of about 80 V and outputs the converted display data to the display device.

The output driver 1 includes a current mirror circuit 10 and an output circuit 20.

The current mirror circuit 10 includes current sources 101 and 102 and input transistors 103 and 104. Each of the current sources 101 and 102 is capable of variable control of a current value and is turned ON/OFF according to control signals S101 and S102, respectively, which correspond to display data. The input transistor 103 has a drain connected to the current source 101 and a source connected to the first potential (e.g., supply potential). The drain and gate of the input transistor 103 are coupled together. The input transistor 104 has a drain connected to the current source 102, a source connected to the first potential, and a gate connected to the gate of the input transistor 103.

The output circuit 20 includes output transistors 105p and 105n. The output transistors 105p and 105n are connected in series between the first potential and the second potential (e.g., ground potential). The gate of the output transistor 105p is supplied with the output of the current mirror circuit 10 (drain voltage of the input transistor 104) Vo. The gate of the output transistor 105n is supplied with control signal S105n which corresponds to display data. The drain voltage of the output transistor 105p is output as output voltage Vout of the output circuit 20.

<Operation>

The operation of the output driver 1 shown in FIG. 1 is described. Herein, the current of the current source 102 obtained when the current source 102 is ON is represented by “I”, the gate-drain capacitance of the output transistor 105p of the output circuit 20 is represented by “C”, the current drivability of the output transistor 105p of the output circuit 20 is represented by “i”, and the load capacitance of the display device is represented by “CL”.

When the display data transitions from “H level” to “L level”, the current source 101 transitions from “OFF” to “ON” in response to control signal S101 while the current source 102 transitions from “ON” to “OFF” in response to control signal S102. Accordingly, a current flows through the input transistor 103 while a current also flows through the input transistor 104 constituting a current mirror structure. As a result, drain voltage Vo of the input transistor 104 approaches “first potential” which is the source potential. When drain voltage Vo reaches a vicinity of “first potential”, the current flowing through the input transistor 104 stops. Since output voltage Vo of the current mirror circuit 10 reaches a vicinity of “first potential”, no current flows through the output transistor 105p of the output circuit 20. Meanwhile, control signal S105n transitions to “H level” so that the output transistor 105n is turned “ON”. Thus, output voltage Vout of the output circuit 20 (drain voltage of the output transistor 105p) reaches a vicinity of “second potential”.

Then, when display data transitions from “L level” to “H level”, the current source 101 transitions from “ON” to “OFF” in response to control signal S101 while the current source 102 transitions from “OFF” to “ON” in response to control signal S102, so that the currents flowing through the input transistors 103 and 104 stop. Meanwhile, control signal S105n transitions to “L level” so that the output transistor 105n is turned “OFF”. Herein, the slew rate of output voltage Vo of the current mirror circuit 10 is “I/C”. If slew rate “I/C” of output voltage Vo is lower than slew rate “i/CL” of output voltage Vout, drain voltage Vout of the output transistor 105p changes according to the change of the gate voltage of the output transistor 105p (i.e., output voltage Vo of the current mirror circuit 10) because of a feedback caused by the gate-drain capacitance of the output transistor 105p. Since slew rate “I/C” of output voltage Vo is constant, drain voltage Vout of the output transistor 105p changes at a constant rate.

<Effects>

As described above, the output voltage can be changed at a constant rate without dependence of the change of the output voltage on the load capacitance. Thus, driving of high quality can be achieved.

### Embodiment 2

<General Structure>

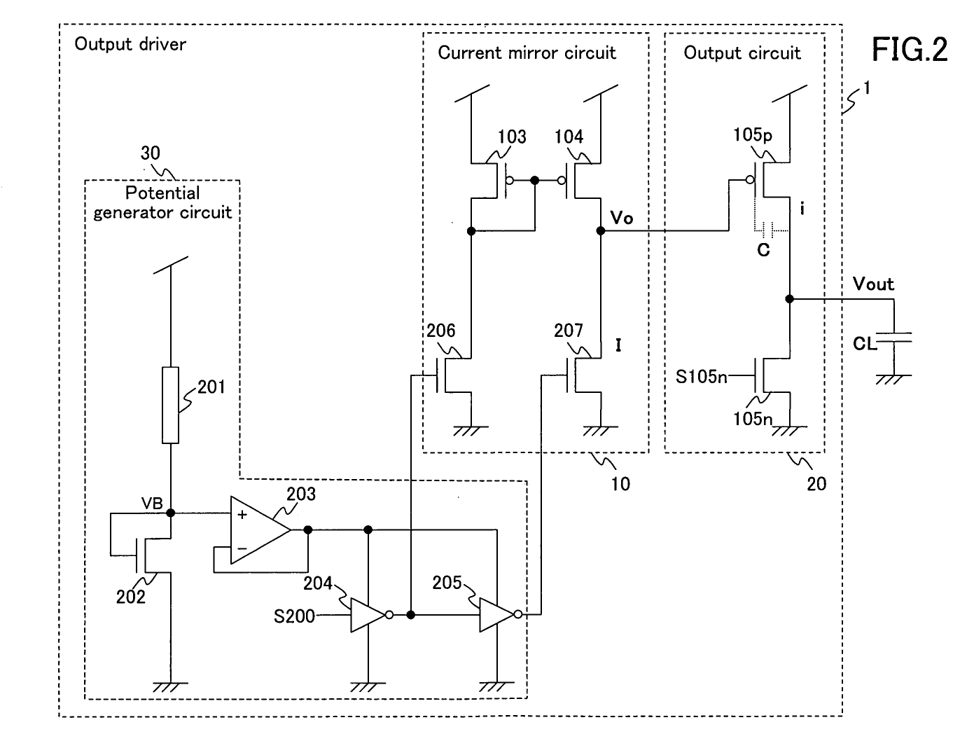

FIG. 2 shows a structure of an output driver according to embodiment 2 of the present invention. The output driver 1 of this embodiment includes a potential generator circuit 30 in addition to the components of the output driver 1 shown in FIG. 1. The current mirror circuit 10 includes transistors for current sources (current source transistors 206 and 207) in place of the current sources 101 and 102. The other aspects of the structure are the same as those of FIG. 1.

The potential generator circuit 30 includes a bias resistor (constant current source) 201, a bias voltage generation transistor 202, a current buffer 203, and binary logic circuits 204 and 205. The bias resistor 201 and bias voltage generation transistor 202 are connected in series between the first potential and the second potential. The gate and drain of the bias voltage generation transistor 202 are coupled together. The current buffer 203 receives a drain voltage of the bias voltage generation transistor 202 (bias voltage VB) at an input terminal. The other input terminal and output terminal of the current buffer 203 are coupled together. Each of the binary logic circuits 204 and 205 receives the output of the current buffer 203 (bias voltage VB) at a power input terminal and the second potential at the other power input terminal. The binary logic circuit 204 outputs any one of “output of the current buffer 203” and “second potential” according to control signal S200 which corresponds to display data. The binary logic circuit 205 outputs any one of “output of the current buffer 203” and “second potential” according to the output of the binary logic circuit 204.

In the current mirror circuit 10, the current source transistor 206 is connected between the input transistor 103 and the second potential and receives the output of the binary logic circuit 204 at the gate. The current source transistor 207 is connected between the input transistor 104 and the second potential and receives the output of the binary logic circuit 205 at the gate.

Although in FIG. 2 each of the binary logic circuits 204 and 205 receives “the output of the current buffer 203” as one supply and “second potential” as the other supply, the binary logic circuit 204 may receive “third potential” which allows any constant current to flow through the current source transistor 206 as one supply and “fourth potential” which allows any current equal to or greater than zero to flow through the current source transistor 206 as the other supply. It should be noted that the third potential is higher than the fourth potential. The binary logic circuit 205 receives “fifth potential” which allows any constant current to flow through the current source transistor 207 as one supply and “sixth potential” which allows any current equal to or greater than zero to flow through the current source transistor 207 as the other supply. It should be noted that the fifth potential is higher than the sixth potential.

Alternatively, the third potential may be equal to the fifth potential, or the fourth potential may be equal to the sixth potential. Alternatively, the third and fifth potentials may be generated by the current buffer 203, or the fourth and sixth potentials may be generated by the current buffer 203.

<Operation>

The operation of the output driver 1 shown in FIG. 2 is described.

When control signal S200 transitions from “bias voltage VB” to “second potential” (i.e., display data transitions from “H level” to “L level”), the output of the binary logic circuit 204 becomes equal to “output of the current buffer (bias voltage VB)” while the output of the binary logic circuit 205 becomes equal to “second potential”. As a result, in the current mirror circuit 10, a current which corresponds to the output of the binary logic circuit 205 (a current determined by bias voltage VB) flows through the current source transistor 206. Meanwhile, the current flowing through the current source transistor 207 stops. A current which has a current value equal to the current of the current source transistor 206 flows through the input transistor 103, and a current also flows through the input transistor 104 constituting a current mirror structure. As a result, drain voltage Vo of the input transistor 104 approaches “first potential” which is the source voltage. When drain voltage Vo reaches a vicinity of “first potential”, the current flowing through the input transistor 104 stops. Since output voltage Vo of the current mirror circuit 10 reaches a vicinity of “first potential”, no current flows through the output transistor 105p of the output circuit 20. Meanwhile, control signal S105n transitions to “H level” so that the output transistor 105n is turned “ON”. Thus, output voltage Vout of the output circuit 20 reaches a vicinity of “second potential”.

Then, when control signal S200 transitions from “second potential” to “bias voltage VB” (i.e., display data transitions from “L level” to “H level”), the output of the binary logic circuit 204 becomes equal to “second potential” while the output of the binary logic circuit 205 becomes equal to “output of the current buffer (bias voltage VB)”. In the current mirror circuit 10, the current flowing through the current source transistor 206 stops, and accordingly, the currents flowing through the input transistors 103 and 104 also stop. Meanwhile, a current which corresponds to the output of the binary logic circuit 205 (a current determined by bias voltage VB) flows through the current source transistor 207. Further, control signal S105n transitions to “L level” so that the output transistor 105n is turned “OFF”. At this point, the slew rate of output voltage Vo of the current mirror circuit 10 is “I/C”. If slew rate “I/C” of output voltage Vo is lower than slew rate “i/CL” of output voltage Vout, drain voltage Vout of the output transistor 105p changes according to the change of the gate voltage of the output transistor 105p (i.e., output voltage Vo of the current mirror circuit 10) because of a feedback caused by the gate-drain capacitance of the output transistor 105p. Since slew rate “I/C” of output voltage Vo is constant, drain voltage Vout of the output transistor 105p changes at a constant rate.

<Effects>

As described above, “bias voltage” and “second potential” are input as supplies to each of the binary logic circuits, and driving of the current source transistors is controlled according to the outputs of the binary logic circuits. With this feature, current ON/OFF control can readily be realized.

### Embodiment 3

<General Structure>

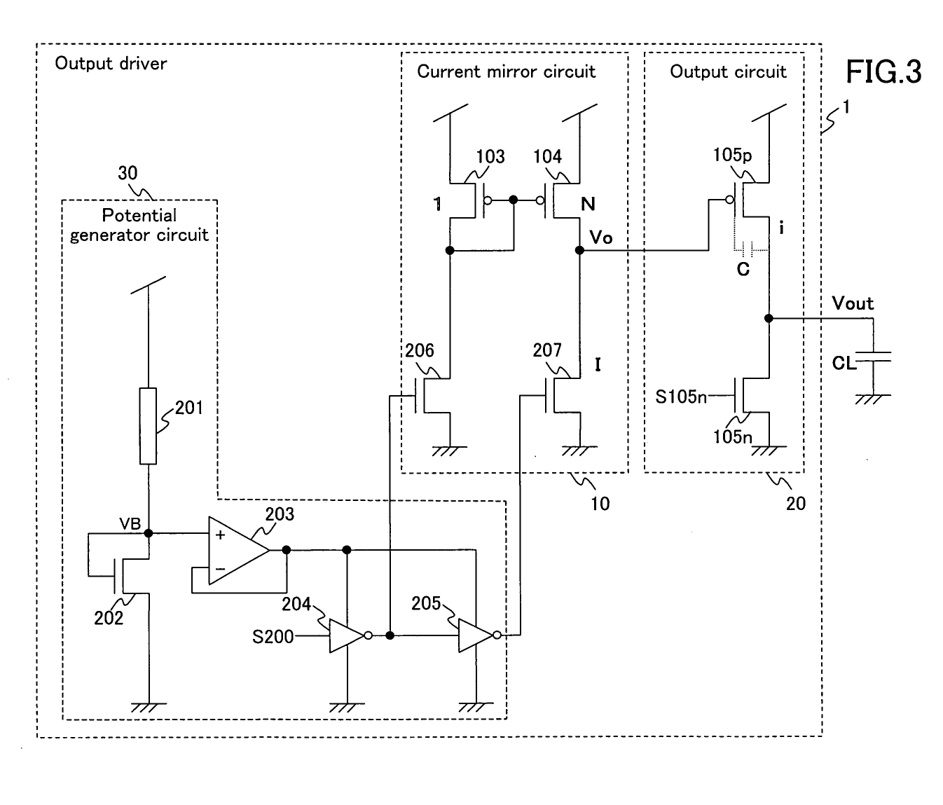

FIG. 3 shows a structure of an output driver 1 according to embodiment 3 of the present invention. The output driver 1 of this embodiment is substantially the same as that of the output driver 1 shown in FIG. 2 except that the input transistors 103 and 104 have different “Channel Width/Channel Length (W/L)” values. The W/L value of the input transistor 103 is smaller than that of the input transistor 104. The ratio between the W/L value of the input transistor 103 and the W/L value of the input transistor 104 is “1:N”.

<Operation>

The operation of the output driver 1 shown in FIG. 3 is described with reference to FIG. 3.

When control signal S200 corresponding to display data transitions from “second potential” to “bias voltage VB”, the output of the binary logic circuit 204 becomes equal to “second potential” while the output of the binary logic circuit 205 becomes equal to “output of the current buffer (bias voltage VB)”. As a result, as in the output driver 1 shown in FIG. 2, the current flowing through the current source transistor 206 stops, while a current which corresponds to the output of the binary logic circuit 205 (a current determined by bias voltage VB) flows through the current source transistor 207. Accordingly, drain voltage Vo of the input transistor 104 approaches “second potential” which is the source potential of the input transistor 104. When drain voltage Vo reaches a vicinity of “second potential”, the current flowing through the current source transistor 207 stops. At this point, control signal S105n transitions to “L level” so that the output transistor 105n is turned “OFF”. Since output voltage Vo of the current mirror circuit 10 reaches a vicinity of “second potential”, a current flows through the output transistor 105p of the output circuit 20, so that output voltage Vout of the output circuit 20 (drain voltage of the output transistor 105p) reaches a vicinity of “first potential”. This output voltage Vout drives load capacitance CL.

Then, when control signal S200 transitions from “bias voltage VB” to “second potential”, the output of the binary logic circuit 204 becomes equal to “output of the current buffer (bias voltage VB)” while the output of the binary logic circuit 205 becomes equal to “second potential”. As a result, in the current mirror circuit 10, a current which corresponds to the output of the binary logic circuit 205 (a current determined by bias voltage VB) flows through the current source transistor 206. Meanwhile, the current flowing through the current source transistor 207 stops. At this point, if the current source transistors 206 and 207 have the same current drivability, the current flowing through the input transistor 104 is N times the current flowing through the input transistor 103. Thus, drain voltage Vo of the input transistor 104 can be transitioned to “first potential” N times faster as compared with the output driver of FIG. 2. When drain voltage Vo of the input transistor 104 reaches a vicinity of “first potential”, the output transistor 105p stops while the current flowing through the input transistor 104 also stops.

<Effects>

As described above, the output transistor of the output circuit can be quickly turned OFF.

### Embodiment 4

<General Structure>

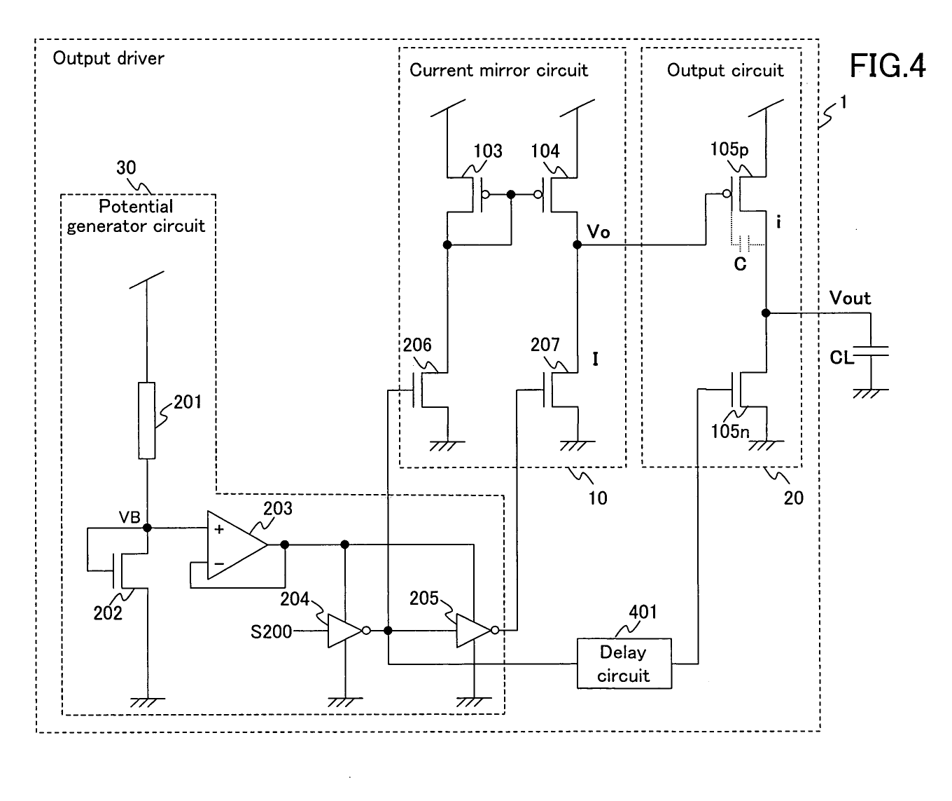

FIG. 4 shows a structure of an output driver according to embodiment 4 of the present invention. The output driver 1 of this embodiment includes a delay circuit 401 in addition to the components of the output driver 1 shown in FIG. 2. The delay circuit 401 delays the output of the binary logic circuit 205. The output transistor 105n receives the output of the delay circuit 401 at the gate in place of control signal S105n. The other aspects of the structure are the same as those of FIG. 2.

<Operation>

The operation of the output driver 1 shown in FIG. 4 is described.

When control signal S200 corresponding to display data transitions from “second potential” to “bias voltage VB”, the output of the binary logic circuit 204 becomes equal to “second potential” while the output of the binary logic circuit 205 becomes equal to “output of the current buffer (bias voltage VB)”. As a result, as in the output driver 1 shown in FIG. 2, the current flowing through the current source transistor 206 stops, while a current which corresponds to the output of the binary logic circuit 205 (a current determined by bias voltage VB) flows through the current source transistor 207. Accordingly, drain voltage Vo of the input transistor 104 approaches “second potential” which is the source potential of the current source transistor 207. When drain voltage Vo reaches a vicinity of “second potential”, the current flowing through the current source transistor 207 stops. Since output voltage Vo of the current mirror circuit 10 reaches a vicinity of “second potential” while the output of the delay circuit 401 reaches “second potential”, a current flows through the output transistor 105p of the output circuit 20 while the current flowing through the output transistor 105n stops. Thus, output voltage Vout of the output circuit 20 (drain voltage of the output transistor 105p) reaches a vicinity of “first potential”. This output voltage Vout drives load capacitance CL.

Then, when control signal S200 transitions from “bias voltage VB” to “second potential”, the output of the binary logic circuit 204 becomes equal to “output of the current buffer (bias voltage VB)” while the output of the binary logic circuit 205 becomes equal to “second potential”. As a result, in the current mirror circuit 10, a current which corresponds to the output of the binary logic circuit 205 (a current determined by bias voltage VB) flows through the current source transistor 206. Meanwhile, the current flowing through the current source transistor 207 stops. At this point, drain voltage Vo of the input transistor 104 approaches “first potential”, but the output transistor 105p of the output circuit 20 is not immediately turned “OFF”. If the output transistor 105n should be turned ON before the output transistor 105p is turned “OFF”, a through current would flow between the output transistors 105p and 105n. However, in this embodiment, the delay circuit 401 delays the time for the output transistor 105n of transition from “OFF” to “ON”, and therefore, the through current is prevented.

<Effects>

As described above, the time of transition for the output transistor of the output circuit from “OFF” to “ON” can be delayed, and therefore, the through current is prevented.

### Embodiment 5

<General Structure>

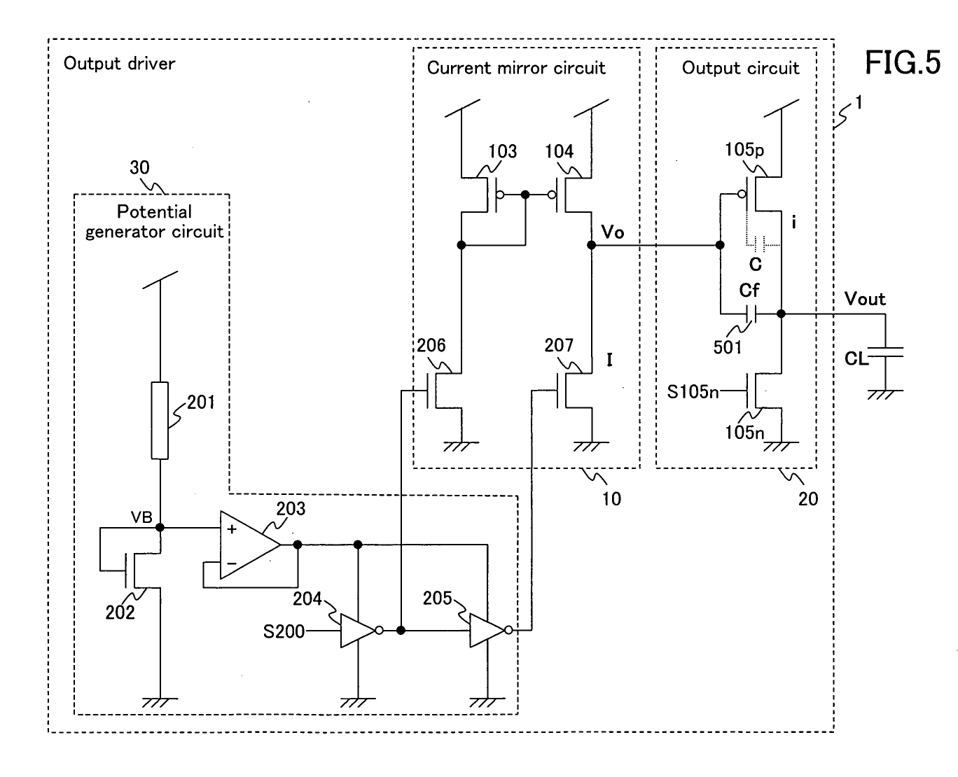

FIG. 5 shows a structure of an output driver according to embodiment 5 of the present invention. The output driver 1 of this embodiment includes a capacitor 501 in addition to the components of the output circuit 20 shown in FIG. 2. The capacitor 501 is connected between the gate and drain of the output transistor 105p.

<Operation>

The operation of the output driver 1 shown in FIG. 5 is described. Herein, the capacitance value of the capacitor 501 is represented by “Cf”.

When control signal S200 transitions from “bias voltage VB” to “second potential”, the output of the binary logic circuit 204 becomes equal to “output of the current buffer (bias voltage VB)” while the output of the binary logic circuit 205 becomes equal to “second potential”. As a result, in the current mirror circuit 10, a current which corresponds to the output of the binary logic circuit 205 (a current determined by bias voltage VB) flows through the current source transistor 206. Meanwhile, the current flowing through the current source transistor 207 stops. A current which has a current value equal to the current of the current source transistor 206 flows through the input transistor 103, and a current also flows through the input transistor 104 constituting a current mirror structure. As a result, drain voltage Vo of the input transistor 104 approaches “first potential” which is the source voltage. When drain voltage Vo reaches a vicinity of “first potential”, the current flowing through the input transistor 104 stops. Since output voltage Vo of the current mirror circuit 10 reaches a vicinity of “first potential”, no current flows through the output transistor 105p of the output circuit 20. Meanwhile, control signal S105n transitions to “H level” so that the output transistor 105n is turned “ON”. Thus, output voltage Vout of the output circuit 20 reaches a vicinity of “second potential”.

Then, when control signal S200 transitions from “second potential” to “bias voltage VB”, the output of the binary logic circuit 204 becomes equal to “second potential” while the output of the binary logic circuit 205 becomes equal to “output of the current buffer (bias voltage VB)”. In the current mirror circuit 10, the current flowing through the current source transistor 206 stops, and accordingly, the currents flowing through the input transistors 103 and 104 also stop. Meanwhile, a current which corresponds to the output of the binary logic circuit 205 (a current determined by bias voltage VB) flows through the current source transistor 207. Further, control signal S105n transitions to “L level” so that the output transistor 105n is turned “OFF”. At this point, the slew rate of output voltage Vo of the current mirror circuit 10 is “I/(C+Cf)”. If slew rate “I/(C+Cf)” of output voltage Vo is lower than slew rate “i/CL” of output voltage Vout, drain voltage Vout of the output transistor 105p changes according to the change of the gate voltage (output voltage Vo) of the output transistor 105p because of a feedback caused by the gate-drain capacitance of the output transistor 105p. Since slew rate “I/(C+Cf)” of output voltage Vo is constant, drain voltage Vout of the output transistor 105p changes at a constant rate.

<Effects>

As described above, the slew rate can be “I/(C+Cf)”. Although in the above-described example the gate-drain capacitance of the output transistor, “C”, exhibits voltage dependency, the additional capacitor (=“Cf”) may not exhibit voltage dependency or may exhibit arbitrary voltage dependency. With such a feature, more optimum control of the slew rate can be achieved.

### Embodiment 6

<General Structure>

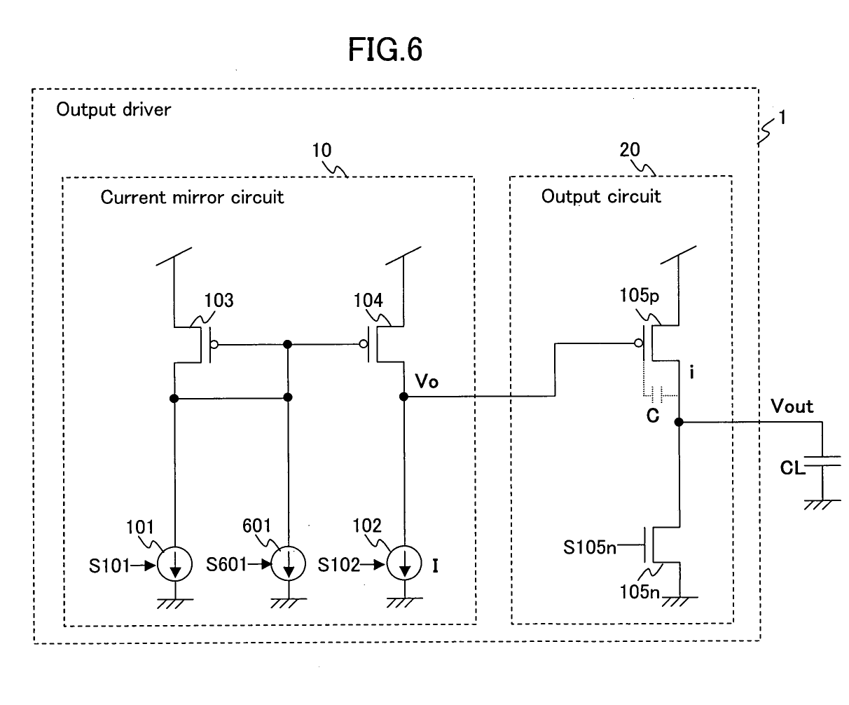

FIG. 6 shows a structure of an output driver according to embodiment 6 of the present invention. The output driver 1 of this embodiment includes a current source 601 in addition to the components of the current mirror circuit 10 shown in FIG. 1. The current source 601 is capable of variable control of the current value. Specifically, the current source 601 is turned ON/OFF according to control signal S601 corresponding to display data. The current source 601 is connected between the drain of the input transistor 103 and the second potential. The current value of a current which flows when the current source 601 is ON is small as compared with the current source 101. The current source 101 is turned “ON” when display data transitions from “H level” to “L level” and, after passage of a predetermined time (a sufficient time for stabilizing the drain voltage of the input transistor 104), returns to “OFF”.

<Operation>

The operation of the output driver 1 shown in FIG. 6 is described.

When display data transitions from “L level” to “H level”, the current sources 101 and 601 transition from “ON” to “OFF” while the current source 102 transitions from “OFF” to “ON”. Accordingly, the current flowing through the input transistor 103 stops, and the current flowing through the input transistor 104 constituting a current mirror structure also stops. As a result, drain voltage Vo of the input transistor 104 is induced to the “second potential” side by the current source 102 so that drain voltage Vo reaches a vicinity of “second potential”. At this point, control signal S105n transitions to “L level” so that the output transistor 105n is turned “OFF”. Since output voltage Vo of the current mirror circuit 10 reaches a vicinity of “second potential”, a current flows through the output transistor 105p of the output circuit 20, so that output voltage Vout of the output circuit 20 (drain voltage of the output transistor 105p) reaches a vicinity of “first potential”.

Then, when display data transitions from “H level” to “L level”, the current sources 101, 102 and 601 receive control signals S101, S102 and S601, respectively, so that the current sources 101 and 601 transition from “OFF” to “ON” while the current source 102 transitions from “ON” to “OFF”. As a result, currents flow through the input transistors 103 and 104. At this point in time, drain voltage Vo of the input transistor 104 approaches “first potential” which is the source voltage. When drain voltage Vo reaches a vicinity of “first potential”, the current flowing through the input transistor 104 stops. Meanwhile, control signal S105n transitions to “H level” so that the output transistor 105n is turned “ON”. Since output voltage Vo of the current mirror circuit 10 reaches a vicinity of “first potential”, no current flows through the output transistor 105p of the output circuit 20, so that output voltage Vout of the output circuit 20 reaches a vicinity of “second potential”. Meanwhile, to prevent a current from continuing to flow through the input transistor 103, the current source 101 stops in response to control signal S101 after drain voltage Vo of the input transistor 104 is stabilized at the vicinity of “first potential”. At this point, the current keeps flowing through the current source 601, so that drain voltage Vo of the input transistor 104 stays at the vicinity of “first potential”.

<Effects>

As described above, the current source 601 which has a small current value as compared with the current source 101 is connected to the drain of the input transistor 103. This feature reduces the through current from the current source 101 and realizes an output driver which requires reduced-power.

### Embodiment 7

<General Structure>

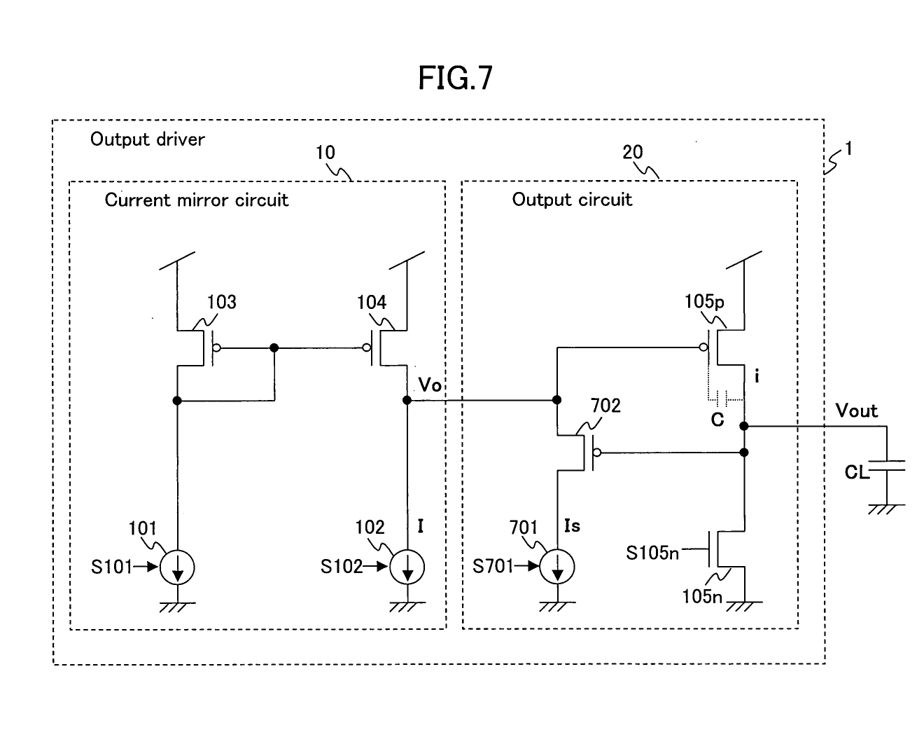

FIG. 7 shows a structure of an output driver according to embodiment 7 of the present invention. The output driver 1 of this embodiment includes a current source 701 and a transistor 702 in addition to the components of the output circuit 20 shown in FIG. 1. The current source 701 is capable of variable control of the current value. Specifically, the current source 701 is turned ON/OFF according to control signal S701 which corresponds to display data. The transistor 702 has a source connected to the gate of the output transistor 105p, a drain connected to the current source 701, and a gate connected to the drain of the output transistor 105p.

<Operation>

The operation of the output driver 1 shown in FIG. 7 is described. Herein, the current of the current source 701 obtained when the current source 701 is ON is represented by “Is”.

When the display data transitions from “H level” to “L level”, the current source 101 transitions from “OFF” to “ON” while the current sources 102 and 701 transition from “ON” to “OFF”. Accordingly, a current flows through the input transistor 103 while a current also flows through the input transistor 104 constituting a current mirror structure. As a result, drain voltage Vo of the input transistor 104 approaches “first potential” which is the source potential. When drain voltage Vo reaches a vicinity of “first potential”, the current flowing through the input transistor 104 stops. Meanwhile, control signal S105n transitions to “H level” so that the output transistor 105n is turned “ON”. Since output voltage Vo of the current mirror circuit 10 reaches a vicinity of “first potential”, no current flows through the output transistor 105p of the output circuit 20. Thus, output voltage Vout of the output circuit 20 (drain voltage of the output transistor 105p) reaches a vicinity of “second potential”.

Then, when display data transitions from “L level” to “H level”, the current source 101 transitions from “ON” to “OFF” while the current sources 102 and 701 transition from “OFF” to “ON”, so that the currents flowing through the input transistors 103 and 104 stop. Meanwhile, control signal S105n transitions to “L level” so that the output transistor 105n is turned “OFF”. At this point, the slew rate of output voltage Vo of the current mirror circuit 10 is “(I+Is)/C”. Thereafter, if the ON conditions of the transistor 702 are dissatisfied because of the relationship between the source voltage of the transistor 702 (output voltage Vo of the current mirror circuit 10) and the gate voltage of the transistor 702 (output voltage Vout of the output circuit 20), namely, if the transistor 702 is turned “OFF”, the slew rate of output voltage Vo results in “I/C”. Herein, in the case where load capacitance CL is small and output voltage Vout of the output circuit 20 changes fast, the slew rate of output voltage Vo of the current mirror circuit 10 decreases within a short period of time as compared with the case where load capacitance CL is large. Therefore, dependency on the output load can be suppressed. If slew rate “I/C” of output voltage Vo is lower than slew rate “i/CL” of output voltage Vout, drain voltage Vout of the output transistor 105p changes according to the change of the gate voltage of the output transistor 105p (output voltage Vo) because of a feedback caused by the gate-drain capacitance of the output transistor 105p. Since slew rate “I/C” of output voltage Vo is constant, drain voltage Vout of the output transistor 105p changes at a constant rate.

<Effects>

As described above, in the case where the load capacitance is small and the output voltage of the output circuit changes fast, the slew rate of the output voltage of the current mirror circuit decreases within a short period of time as compared with the case where the load capacitance is large. Therefore, dependency on the output load can be suppressed.

### Embodiment 8

<General Structure>

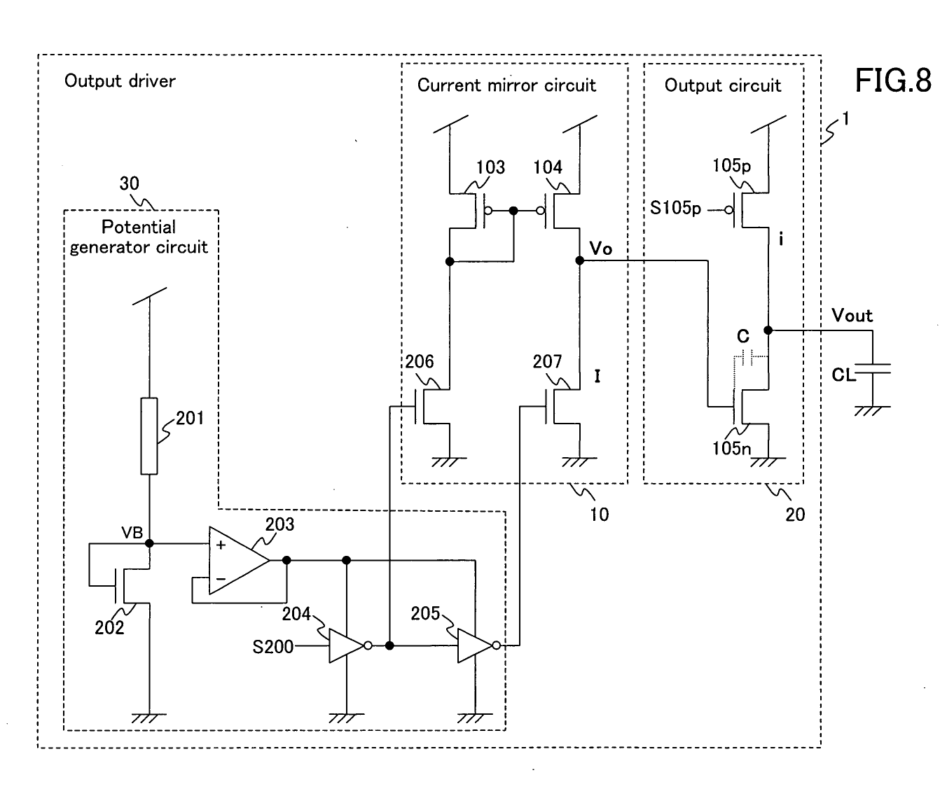

FIG. 8 shows a structure of an output driver according to embodiment 8 of the present invention. The output driver 1 of this embodiment has substantially the same structure as the output driver 1 shown in FIG. 2 except for different connections in the output circuit 20. The output transistor 105p receives control signal S105p at the gate in place of output voltage Vo of the current mirror circuit 10. The output transistor 105n receives output voltage Vo of the current mirror circuit 10 at the gate in place of control signal S105p.

<Operation>

The operation of the output driver 1 shown in FIG. 8 is described. Herein, the current which flows through the current source transistor 207 when the current source transistor 207 is ON is represented by “I”, the gate-drain capacitance of the output transistor 105n of the output circuit 20 is represented by “C”, the current drivability of the output transistor 105n of the output circuit 20 is represented by “i”, and the load capacitance of the display device is represented by “CL”.

When control signal S200 transitions from “second potential” to “bias voltage VB” (i.e., display data transitions from “L level” to “H level”), the output of the binary logic circuit 204 becomes equal to “second potential” while the output of the binary logic circuit 205 becomes equal to “bias voltage VB”. As a result, the current flowing through the current source transistor 206 stops, and accordingly, the currents flowing through the input transistors 103 and 104 also stop. Meanwhile, a current which corresponds to the output of the binary logic circuit 205 (a current determined by bias voltage VB) flows through the current source transistor 207. Accordingly, drain voltage Vo of the current source transistor 207 approaches “second potential” which is the source voltage. When drain voltage Vo reaches a vicinity of “second potential”, the current flowing through the current source transistor 207 stops. At this point, control signal S105p transitions to “L level” so that the output transistor 105p is turned “ON”. Since output voltage Vo of the current mirror circuit 10 reaches a vicinity of “second potential”, no current flows through the output transistor 105n of the output circuit 20, so that output voltage Vout of the output circuit 20 (drain voltage of the output transistor 105n) reaches a vicinity of “first potential”.

Then, when control signal S200 transitions from “bias voltage VB” to “second potential” (i.e., display data transitions from “H level” to “L level”), the output of the binary logic circuit 204 becomes equal to “bias voltage VB” while the output of the binary logic circuit 205 becomes equal to “second potential”. As a result, the current flowing through the current source transistor 207 stops. Meanwhile, a current which corresponds to the output of the binary logic circuit 204 (a current determined by bias voltage VB) flows through the current source transistor 206. A current which has a current value equal to the current of the current source transistor 206 flows through the input transistor 103, and a current also flows through the input transistor 104 constituting a current mirror structure. Meanwhile, control signal S105p transitions to “H level” so that the output transistor 105p is turned “OFF”. At this point, the slew rate of output voltage Vo of the current mirror circuit 10 is “I/C”. If slew rate “I/C” of output voltage Vo is lower than slew rate “i/CL” of output voltage Vout, drain voltage Vout of the output transistor 105n changes according to the change of the gate voltage of the output transistor 105n (output voltage Vo) because of a feedback caused by the gate-drain capacitance of the output transistor 105n. Since slew rate “I/C” of output voltage Vo is constant, drain voltage Vout of the output transistor 105n changes at a constant rate.

<Effects>

As described above, the change of the output voltage of the output circuit does not depend on the load capacitance in the case where the output voltage of the current mirror circuit is supplied to an N-channel transistor of the output circuit as well as in the case where it is supplied to a P-channel transistor of the output circuit. Thus, driving of high quality can be realized.

### Embodiment 9

<General Structure>

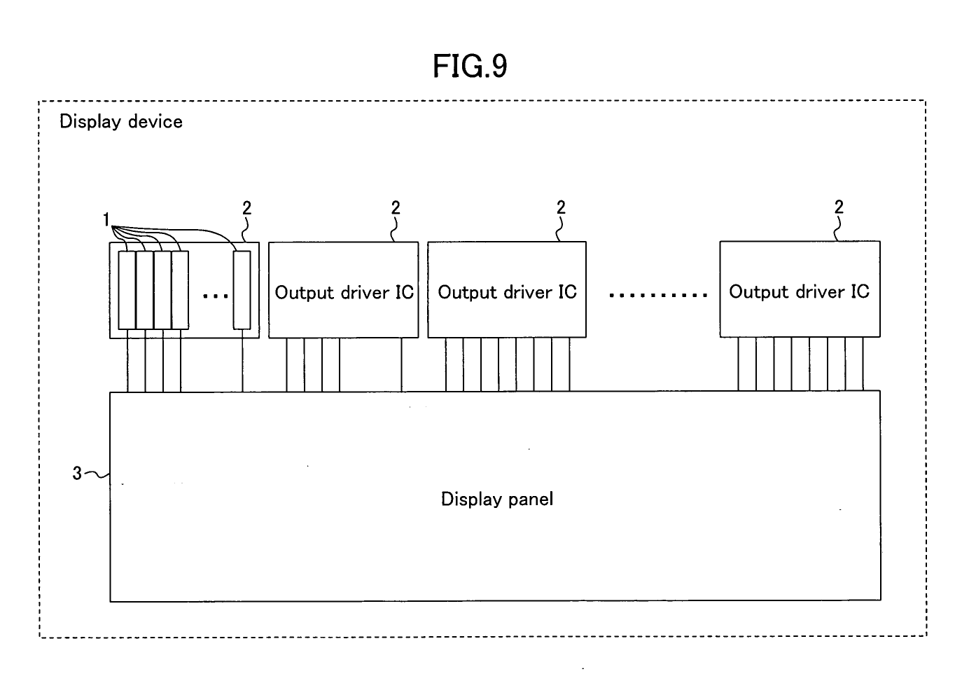

FIG. 9 shows a structure of a display device according to embodiment 9 of the present invention. The display device includes a plurality of output driver ICs 2 and a display panel 3. Each of the output driver ICs 2 includes a plurality of output drivers 1 shown in any of FIG. 1 through FIG. 8 and has a number of output terminals equal to the number of output drivers 1 incorporated therein. In an application where the output driver ICs 2 are mounted on the display panel 3, the output terminals of the output driver ICs 2 are connected to the display panel 3.

<Operation>

The operation of the display device shown in FIG. 9 is described. The output terminals of the output driver ICs are wired to pixels of the display panel 3. Therefore, the distance between the wires is short, so that capacitance coupling occurs between the wires. The effects caused by the capacitance between adjoining output terminals are not uniform because the adjoining output terminals operate according to display data supplied to corresponding output drivers 1. For example, when a certain output terminal and an output terminal adjacent thereto transition with the same tendency (e.g., when both output terminals transition from “H level” to “L level”), the load capacitances for the respective output terminals look as if they are relatively decreased. When the output terminals transition with the opposite tendencies (e.g., when the first output terminal transitions from “H level” to “L level” while the second output terminal transitions from “L level” to “H level”), the load capacitances for the respective output terminals look as if they are relatively increased. An output terminal sandwiched by two adjacent output terminals provided on both sides, one on a side and the other on the other side, can be affected twofold by the adjacent output terminals (namely, the decrease/increase of the capacitive load can be twofold). To achieve high display quality, it is necessary to avoid variations in the output waveform which would be caused by such variations in the load conditions. Using any of the output drivers 1 shown in FIG. 1 through FIG. 8 enables driving with small load dependency.

<Effects>

As described above, driving is realized with small load dependency. Therefore, driving is realized with stable output waveform irrespective of the largeness of wire load coupling capacitance due to display data. Thus, a display device capable of displaying high quality images can be realized.

An output driver and display device according to the present invention relate to a capacitive load driver and are especially useful for a display driver for PDP (Plasma Display Panel), etc. Also, the output driver is applicable to a driver for a liquid crystal panel which utilizes high breakdown voltage processes.

What is claimed is:

1. An output driver, comprising:
first and second current sources which are turned ON/OFF according to display data;
a first input transistor which has a source connected to a first potential, a drain connected to a second potential via the first current source, and a gate, the drain and the gate being coupled together;
a second input transistor which has a source connected to the first potential, a drain connected to the second potential via the second current source, and a gate receiving a gate voltage of the first input transistor;
a first output transistor which has a source connected to the first potential, a drain, and a gate receiving the drain voltage of the second input transistor; and
a second output transistor which has a source connected to the second potential, a drain connected to the drain of the first output transistor, and a gate receiving a control signal corresponding to the display data.

2. The output driver of claim 1, wherein:
the display data has first and second phases;
when the display data is in the first phase, the first current source is ON, the second current source is OFF, and the second output transistor is ON; and
when the display data is in the second phase, the first current source is OFF, the second current source is ON, and the second output transistor is OFF.

3. The output driver of claim 1, wherein:
the first current source is a first current source transistor which has a source connected to the second potential, a drain connected to the drain of the first input transistor, and a gate receiving an arbitrary constant voltage; and
the second current source is a second current source transistor which has a source connected to the second potential, a drain connected to the drain of the second input transistor, and a gate receiving an arbitrary constant voltage.

4. The output driver of claim 3, further comprising:
a first binary logic circuit that receives a third potential which allows an arbitrary constant current to flow through the first current source transistor and a fourth potential which allows an arbitrary current equal to or greater than zero to flow through the first current source transistor and outputs any one of the third potential and the fourth potential according to a first control signal which corresponds to the display data; and
a second binary logic circuit that receives a fifth potential which allows an arbitrary constant current to flow through the second current source transistor and a sixth potential which allows an arbitrary current equal to or greater than zero to flow through the second current source transistor and outputs any one of the fifth potential and the sixth potential according to a second control signal which corresponds to the display data,
wherein the first current source transistor receives the output of the first binary logic circuit at the gate,
the second current source transistor receives the output of the second binary logic circuit at the gate,
the third potential is higher than the fourth potential, and
the fifth potential is higher than the sixth potential.

5. The output driver of claim 4, wherein:
the third and fifth potentials are equal; and
the fourth and sixth potentials are equal.

6. The output driver of claim 4, further comprising:
a constant current source;
a bias voltage generation transistor which has a source connected to the second potential, a drain connected to the first potential via the constant current source, and a gate, the drain and the gate being coupled together; and
a current buffer circuit which amplifies a gate voltage of the bias voltage generation transistor and outputs the amplified gate voltage as the third and fifth potentials.

7. The output driver of claim 4, further comprising:
a constant current source;
a bias voltage generation transistor which has a source connected to the second potential, a drain connected to the first potential via the constant current source, and a gate, the drain and the gate being coupled together; and
a current buffer circuit which amplifies a gate voltage of the bias voltage generation transistor and outputs the amplified gate voltage as the fourth and sixth potentials.

8. The output driver of claim 4, wherein:
the first and second control signals have first and second phases;
the first binary logic circuit outputs the fourth potential when the first control signal is in the first phase and outputs the third potential when the first control signal is in the second phase; and
the second binary logic circuit outputs the sixth potential when the second control signal is in the first phase and outputs the fifth potential when the second control signal is in the second phase.

9. The output driver of claim 1, wherein the value of channel width/channel length of the first input transistor is smaller than that of the second input transistor.

10. The output driver of claim 8, further comprising a delay circuit for delaying the output of the first binary logic circuit, wherein:
the second binary logic circuit receives the output of the first binary logic circuit as the second control signal and outputs the fifth potential when the output of the second binary logic circuit is the fourth potential and outputs the sixth potential when the output of the first binary logic circuit is the third potential; and
the second output transistor receives the output of the delay circuit as the control signal at the gate and is ON when the output of the delay circuit is the third potential and is OFF when the output of the delay circuit is the fourth potential.

11. The output driver of claim 1, further comprising a capacitor which is connected between the gate and drain of the first output transistor.

12. The output driver of claim 2, further comprising a third current source which is connected between the drain of the first input transistor and the second potential, which is turned ON/OFF according to the display data, and which supplies a current having a current value smaller than that of the first current source, wherein
the third current source is ON when the display data is in the first phase and is OFF when the display data is in the second phase; and
the first current source is turned ON when the display data transitions from the second phase to the first phase and is then turned OFF after passage of a predetermined period which is necessary for stabilizing the drain voltage of the second input transistor.

13. The output driver of claim 1, further comprising:
a fourth current source which is turned ON/OFF according to the display data; and
a transistor which has a source connected to the gate of the first output transistor, a drain connected to the second potential via the fourth current source, and a gate connected to the drain of the first output transistor.

14. An output driver, comprising:
first and second current sources which are turned ON/OFF according to display data;
a first input transistor which has a source connected to a first potential, a drain connected to a second potential via the first current source, and a gate, the drain and the gate being coupled together;
a second input transistor which has a source connected to the first potential, a drain connected to the second potential via the second current source, and a gate receiving a gate voltage of the first input transistor;
a first output transistor which has a source connected to the first potential, a drain, and a gate receiving a control signal corresponding to the display data; and
a second output transistor which has a source connected to the second potential, a drain connected to the drain of the first output transistor, and a gate receiving a drain voltage of the second input transistor.

15. A display device, comprising:
a plurality of output drivers which operate according to display data; and
a display panel which receives outputs from the plurality of output drivers,
wherein each of the plurality of output drivers includes
first and second current sources which are turned ON/OFF according to the display data,
a first input transistor which has a source connected to a first potential, a drain connected to a second potential via the first current source, and a gate, the drain and the gate being coupled together,
a second input transistor which has a source connected to the first potential, a drain connected to the second potential via the second current source, and a gate receiving a gate voltage of the first input transistor,
a first output transistor which has a source connected to the first potential, a drain, and a gate receiving the drain voltage of the second input transistor, and
a second output transistor which has a source connected to the second potential, a drain connected to the drain of the first output transistor, and a gate receiving a control signal corresponding to the display data.
